(19) United States
(12) Patent Application Publication
(10) Pub. No.: US 2025/0278025 A1
(43) Pub. Date: Sep. 4, 2025

(54) EUV OPTICS MODULE FOR AN EUV PROJECTION EXPOSURE APPARATUS

(71) Applicant: Carl Zeiss SMT GmbH, Oberkochen (DE)

(72) Inventors: Moritz BECKER, Aalen (DE); Udo DINGER, Oberkochen (DE); Stephanus FENGLER, Aalen (DE)

(21) Appl. No.: 19/210,130

(22) Filed: May 16, 2025

Related U.S. Application Data
(63) Continuation of application No. PCT/EP2023/081090, filed on Nov. 8, 2023.

(30) Foreign Application Priority Data
Nov. 16, 2022 (DE) 10 2022 212 168.6

(51) Int. Cl. G03F 7/00

(52) U.S. Cl. CPC G03F 7/70233; G03F 7/70033; G03F 7/70883

(57) ABSTRACT

An EUV optics module (35) for an EUV projection exposure apparatus (1) has at least one optical component (19, 21, 23, 7, M1 to M6, 13) having an optical surface guiding used EUV radiation (16) from an EUV source (3) along an illuminating and/or imaging beam path of the projection exposure apparatus (1). The optical component (19, 21, 23, 7, M1 to M6, 13) is accommodated in a reduced-pressure chamber (36). A gas source (37) is fluidically connected via at least one valve to the reduced-pressure chamber (36). The gas source (37) is configured to provide at least the following gas: hydrogen. This results in an EUV optics module having elevated operating time.

### CROSS REFERENCE TO RELATED APPLICATIONS

This is a Continuation of International Application PCT/EP2023/081090 which has an international filing date of Nov. 8, 2023, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2022 212 168.6 filed on Nov. 16, 2022.

### FIELD

The invention relates to an EUV optics module for an EUV projection exposure apparatus. The invention further relates to an optical system for an EUV projection exposure apparatus comprising such an EUV optics module, to a projection exposure apparatus comprising such an optical system, to a method of producing a micro- or nanostructured component with the aid of such a projection exposure apparatus, and to a micro- or nanostructured component produced by such a method.

### BACKGROUND

An EUV optics module for an EUV projection exposure apparatus having an EUV source for generation of used extreme ultraviolet (EUV) radiation is known from U.S. Pat. No. 7,598,508 B2 for example. DE 10 2021 202 802 B3 discloses a projection exposure apparatus comprising a device for determining a concentration of atomic hydrogen. DE 10 2017 213 406 A1 discloses a reflective optical element for EUV lithography and a method of adjusting a geometry of a component. DE 10 2016 208 850 A1 discloses a projection exposure apparatus for semiconductor lithography having elements for plasma conditioning. DE 10 2020 202 179 A1 discloses an optical arrangement for EUV lithography and a method of determining a desired value for a target plasma parameter. US 2010/0071720 A1 discloses a method and a system for removal of contamination from a surface. US 2011/0143288 A1 discloses a radiation source, a lithography system and a component production method. US 2012/0086925 A1 discloses a method of avoiding contamination and an EUV lithography system. US 2007/0012889 A1 discloses gaseous spectral purity filters for EUV and an optical system comprising them.

### SUMMARY

It is an object to develop an EUV optics module of the type specified in the Background section, above, such that an operating time of the EUV projection exposure apparatus is increased.

This and other objects are addressed, according to one formulation, by an EUV optics module having the features specified in the independent claims of the present application.

It has been recognized that hydrogen as the gas provided leads to creation of activated hydrogen species. This may be utilized in particular for generation of cleaning radicals with which the optical surface of the optical component is cleaned effectively. This increases the operating time of the EUV optics module. By definition of a partial hydrogen pressure, it is possible to achieve a desired generation of activated hydrogen species in the reduced-pressure chamber. The gas source can also be used to provide further gas species, for example oxygen or nitrogen or a mixture of two or more gas species. The gas source may have multiple gas source units, each of which is used to provide a particular gas. The gas source may have at least one gas vessel. The gas source may have two or more gas vessels containing different gases. Each of these gas vessels may then belong to a respective gas source unit. It is also possible to provide isotopes of the at least one gas provided. In the case of hydrogen, these are D₂HD, T₂TD, HT (D: deuterium; T: tritium). By way of the addition of the hydrogen isotopes, it is possible to increase the effective cross section for dissociative generation of reactive hydrogen species proportionally by up to three orders of magnitude and hence to adjust the reactivity of the hydrogen in the environment of the gas injection. The reduced-pressure chamber may accommodate multiple optical components for which correspondingly activated hydrogen species and/or nitrogen/oxygen species are then generated via the gas provided, which accomplish effective cleaning and/or reaction of the optical surfaces of the optical components. Especially those optical components that are closest to the projection exposure apparatus in the beam path of the used EUV radiation in an EUV source can achieve a higher operating time in this way.

It is also possible to provide isotopes of these gases or vapors via the gas source, especially in a controlled concentration. In each case, open-loop control of the addition of gas is possible, or closed-loop control with respect to the partial pressure.

An isotope content in the concentration range according to an exemplary embodiment has been found to be particularly advantageous. Depending on the type of gas used, an advantageous increase in a cross section of dissociation may arise here, with especially uniform ionization cross section. The isotope content may be within an isotope concentration range between 0.1% and 10%.

The isotope concentration can be controlled by closed-loop control via the state of operation according to a further embodiment using states of operation that have already been described above in connection with the control valve design of the EUV optics module.

A control valve according to an exemplary embodiment enables provision under open-loop or even closed-loop control of the at least one gas via the gas source within the reduced-pressure chamber. It is possible to provide two or more control valves of this kind. In that case, it is possible in each case to assign at least one of the control valves to each of the gas source units or to each of the gas vessels of the gas source. The open-loop/closed-loop control device may be designed such that a respective partial pressure of the at least one gas provided is defined depending on a state of operation of the EUV optics module or of the projection exposure apparatus. This can be accomplished using a look-up table. States of operation may be defined via measurements of the gas composition, especially of H2, N2, NH3, O2, H2O, and/or measurements of the concentration of activated species, especially H, N and O radicals or ions, and/or of the measured or calculated temperature of an optical element. In particular, a state of operation can also be defined via the measurement of a change in the reflective layer of an optical element.

The use of at least one pressure sensor according to a further embodiment allows definition of the partial pressure of the at least one gas provided under closed-loop control. The EUV optics module may have a plurality of such pressure sensors. In that case, at least one of these pressure sensors may be assigned to each gas species and/or to each gas source unit and/or to each gas vessel of the gas source. If nitrogen and hydrogen, for example, are provided via the gas source, one of the pressure sensors can specifically measure a partial nitrogen pressure and the other of the pressure sensors can specifically measure a partial hydrogen pressure. The respective pressure sensor may especially also be assigned to the respective optical component.

A design according to another exemplary embodiment optimizes the function of the EUV optics module in the environment of the optical surface of the optical component. In particular, the EUV optics module may then have a pressure sensor that assures measurement of pressure in the environment of the optical surface of the optical component. It is also possible for two or more pressure sensors of this kind assigned to exactly one optical surface or else assigned to more than one optical surfaces to be part of the EUV optics module.

A partial hydrogen pressure according to further embodiments has been found to be particularly suitable for assurance of a function of the EUV optics module.

Further gases provided via the gas source according to other embodiments have likewise been found to be particularly suitable for achievement of the function of the EUV optics module for increasing the operating time of the at least one optical component.

It is also possible to use a noble gas.

The advantages of an optical system, a projection exposure apparatus, a production method and a microstructured or nanostructured component, all associated with the disclosed optics module correspond to those which have already been described above with reference to the EUV optics module.

The EUV light source of the projection exposure apparatus may be designed so as to result in a used wavelength of not more than 13.5 nm, of less than 13.5 nm, of less than 10 nm, of less than 8 nm, of less than 7 nm, and of 6.7 nm or 6.9 nm, for example. A used wavelength of less than 6.7 nm and, in particular, in the region of 6 nm is also possible.

In particular, the projection exposure apparatus can be used to produce a semiconductor component, for example a memory chip.

### BRIEF DESCRIPTION OF THE DRAWINGS

At least one working example of the invention is described hereinafter with reference to the drawing. The drawing shows:

FIG. 1 a schematic in meridional cross section of a projection exposure apparatus for EUV projection lithography;

FIG. 2 a diagram of a dependence of an effective cross section σ, which is proportional to the absorption of light at particular wavelengths, of particular particle species on the partial pressure p thereof;

FIG. 3 results of a model calculation of a relative transmission T normalized to an in-band transmission for various particle species for a first, lowest partial pressure p=0.001 for various wavelength ranges;

FIGS. 4 to 6 each in a representation similar to FIG. 3, the relative transmissions of these particle species, each at a higher partial pressure p of these particle species, specifically in steps of one order of magnitude, i.e., p=0.010 Pa in FIG. 4, p=0.100 Pa in FIG. 5, and p=1.000 Pa in FIG. 6;

FIG. 7 the dependence of an effective effective cross section σ of nitrogen (N2), adjacent to a mirror substrate surface, on a nitrogen gas pressure p adjustable via a nitrogen source, with observation of photoinduced ionization of a nitrogen molecule;

FIG. 8 the dependence of an effective effective cross section σ of nitrogen (N2), adjacent to a mirror substrate surface, this time on partial pressures p firstly of various elemental vapors, with observation of the photoinduced splitting of a nitrogen molecule into two nitrogen atoms;

FIG. 9 the dependence of an effective effective cross section σ of nitrogen (N₂), adjacent to a mirror substrate surface, on an isotope concentration c of deuterium D₂ in hydrogen H₂ within a reduced-pressure chamber of the projection exposure apparatus.

### DETAILED DESCRIPTION

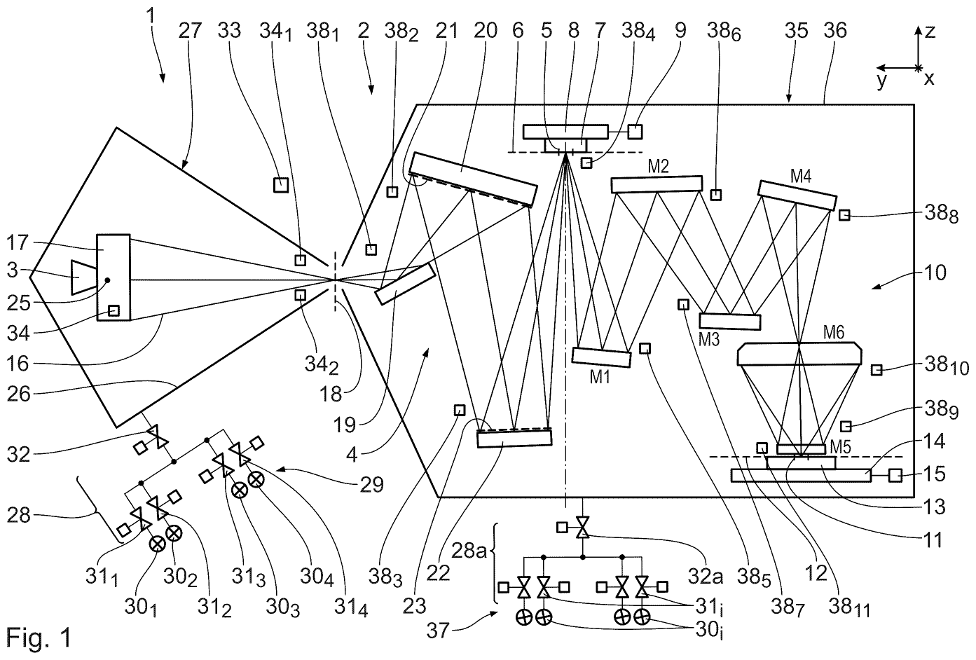

The primary components of a projection exposure apparatus 1 for microlithography are first described by way of example hereinafter with reference to FIG. 1. The description of the basic structure of the projection exposure apparatus 1 and its components should not be regarded as limiting here.

One design of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 disposed in the object field 5 is exposed. The reticle 7 is held by a reticle holder 8. The reticle holder 8 is displaceable, in particular in a scanning direction, by way of a reticle displacement drive 9.

FIG. 1 shows a Cartesian xyz coordinate system by way of facilitating the description. The x direction runs perpendicular to the plane of the drawing. The y direction runs horizontally, and the z direction runs vertically. The scanning direction runs in the y direction in FIG. 1. The z direction runs perpendicular to the object plane 6.

The projection exposure apparatus 1 further comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable, in particular in the y direction, by way of a wafer displacement drive 15. The displacement firstly of the reticle 7 by way of the reticle displacement drive 9, and secondly of the wafer 13 by way of the wafer displacement drive 15, can be implemented so as to be mutually synchronized.

The radiation source 3 is an EUV radiation source or EUV source. The radiation source 3 emits, in particular, EUV radiation 16, which is also referred to below as used radiation, illumination radiation or illumination light. In particular, the used radiation has a wavelength in the range between 5 nm and 30 nm. The radiation source 3 may be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emanating from the radiation source 3 is focused by a collector 17. The collector 17 may be a collector with one or more ellipsoidal and/or hyperboloid reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, having the radiation source 3 and the collector 17, and the illumination optical unit 4.

The illumination optical unit 4 comprises a deflection mirror 19 and, downstream thereof in the beam path, a first facet mirror 20. The deflection mirror 19 may be a planar deflection mirror or, alternatively, a mirror with a beam-influencing effect going beyond the pure deflection effect. As an alternative or in addition, the deflection mirror 19 may be designed as a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of these facets 21 by way of example.

The first facets 21 may be embodied as macroscopic facets, in particular as rectangular facets or as facets with an arcuate or part-circular edge contour. The first facets 21 may be in the form of plane facets or alternatively of facets with convex or concave curvature.

As is known for example from DE 10 2008 009 600 A1, the first facets 21 themselves may also each be composed of a multiplicity of individual mirrors, in particular a multiplicity of micromirrors. The first facet mirror 20 may in particular take the form of a microelectromechanical system (MEMS system). For details, reference is made to DE 10 2020 212 351 A1, to U.S. Pat. No. 10,139,618, to U.S. Pat. No. 9,874,819, to U.S. Pat. No. 9,851,555 and to DE 10 2008 009 600 A1, and to the references cited therein.

The illumination radiation 16 travels horizontally, i.e. in the y direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. Reference is likewise made in this respect to DE 10 2008 009 600 A1 and to the references already mentioned above.

The second facets 23 may have plane reflection surfaces or alternatively reflection surfaces with convex or concave curvature.

The illumination optical unit 4 thus forms a double-faceted system. This basic principle is also referred to as a fly's eye integrator.

It may be advantageous to arrange the second facet mirror 22 not exactly in a plane that is optically conjugate to a pupil plane of the projection optical unit 10. In particular, the pupil facet mirror 22 may be arranged so as to be tilted relative to a pupil plane of the projection optical unit 10, as described, for example, in DE 10 2017 220 586 A1.

The individual first facets 21 are imaged into the object field 5 using the second facet mirror 22. The second facet mirror 22 is the last beam-shaping mirror or else indeed the last mirror for the illumination radiation 16 in the beam path upstream of the object field 5.

In a further embodiment (not illustrated) of the illumination optical unit 4, a transfer optical unit may be arranged in the beam path between the second facet mirror 22 and the object field 5, and contributes in particular to the imaging of the first facets 21 into the object field 5. The transfer optical unit may comprise exactly one mirror or, alternatively, two or more mirrors, which are arranged in succession in the beam path of the illumination optical unit 4. The transfer optical unit may in particular comprise one or two normal-incidence mirrors (NI mirrors) and/or one or two grazing-incidence mirrors (GI mirrors).

In the design shown in FIG. 1, the illumination optical unit 4 has exactly three mirrors downstream of the collector 17, specifically the deflection mirror 19, the field facet mirror 20, and the pupil facet mirror 22.

The deflection mirror 19 may also be omitted in a further design of the illumination optical unit 4, and so the illumination optical unit 4 may then have exactly two mirrors downstream of the collector 17, specifically the first facet mirror 20 and the second facet mirror 22.

The imaging of the first facets 21 into the object plane 6 with the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors MI to M6. Alternatives with four, eight, ten, twelve, or any other number of mirrors Mi are likewise possible. The projection optical unit 10 is a doubly obscured optical unit. The penultimate mirror M5 and the last mirror M6 each have a through opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi may be designed as freeform surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, in particular with alternating layers of molybdenum and silicon.

The projection optical unit 10 has a large object-image offset in the y direction between a y coordinate of a center of the object field 5 and a y coordinate of the center of the image field 11. In the y direction, this object-image offset can be of approximately the same magnitude as a z distance between the object plane 6 and the image plane 12.

The projection optical unit 10 may in particular have an anamorphic form. In particular, it has different imaging scales βx, βy in x and y directions. The two imaging scales βx, βy of the projection optical unit 10 are preferably at (βx, βy)=(+/−0.25, /+−0.125). A positive imaging scale β means imaging without image inversion. A negative sign for the imaging scale β means imaging with image inversion.

The projection optical unit 10 consequently leads to a reduction in size with a ratio of 4:1 in x direction, i.e. in a direction perpendicular to the scanning direction.

The projection optical unit 10 leads to a reduction in size of 8:1 in y direction, i.e. in scanning direction.

Other imaging scales are likewise possible. Imaging scales with the same signs and the same absolute values in x direction and y direction are also possible, for example with absolute values of 0.125 or 0.25.

The number of intermediate image planes in the x direction and in the y direction in the beam path between the object field 5 and the image field 11 may be the same or may differ depending on the design of the projection optical unit 10. Examples of projection optical units with different numbers of such intermediate images in x and y directions are known from US 2018/0074303 A1.

One of the pupil facets 23 in each case is assigned to exactly one of the field facets 21, in each case to form an illumination channel for illuminating the object field 5. This may in particular result in illumination according to the Köhler principle. The far field is deconstructed into a multiplicity of object fields 5 via the field facets 21. The field facets 21 generate a plurality of images of the intermediate focus on the pupil facets 23 respectively assigned thereto.

The field facets 21 are imaged, each by way of an assigned pupil facet 23, onto the reticle 7 in a manner such that they are mutually superposed for illumination of the object field 5. The illumination of the object field 5 is in particular as homogeneous as possible. It preferably has a uniformity error of less than 2%. Field uniformity can be achieved by overlaying different illumination channels.

The illumination of the entrance pupil of the projection optical unit 10 may be geometrically defined by an arrangement of the pupil facets. It is possible to set the intensity distribution in the entrance pupil of the projection optical unit 10 by selecting the illumination channels, in particular the subset of pupil facets, which guide light. This intensity distribution is also referred to as illumination setting or illumination pupil filling.

A likewise preferred pupil uniformity in the region of sections of an illumination pupil of the illumination optical unit 4 which are illuminated in a defined manner may be achieved by a redistribution of the illumination channels.

Further aspects and details of the illumination of the object field 5 and in particular of the entrance pupil of the projection optical unit 10 are described hereinafter.

The projection optical unit 10 may in particular have a homocentric entrance pupil. The latter may be accessible. It may also be inaccessible.

The entrance pupil of the projection optical unit 10 generally cannot be illuminated exactly with the pupil facet mirror 22. The aperture rays often do not intersect at a single point when imaging the projection optical unit 10 which telecentrically images the center of the pupil facet mirror 22 onto the wafer 13. However, it is possible to find an area in which the spacing of the aperture rays that is determined in pairs becomes minimal. This area represents the entrance pupil or an area in real space that is conjugate thereto. In particular, this area has a finite curvature.

It may be the case that the projection optical unit 10 has different poses of the entrance pupil for the tangential beam path and for the sagittal beam path. In this case, an imaging element, in particular an optical component part of the transfer optical unit, should be provided between the second facet mirror 22 and the reticle 7. With this optical element, the different pose of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is in a tilted arrangement with respect to the object plane 6. The first facet mirror 20 is in a tilted arrangement with respect to an arrangement plane defined by the deflection mirror 19.

The first facet mirror 20 is in a tilted arrangement with respect to an arrangement plane defined by the second facet mirror 22.

In the source operation of the EUV source 3, the used EUV radiation 16 is emitted by a source region 25. This source region 25, the collector 17 and also components of the EUV source 3 are accommodated in a reduced-pressure chamber 26 of an EUV source module 27 of the projection exposure apparatus 1. Part of the EUV source module 27 is the EUV source 3.

A gas source 29 of the EUV source module 27 is in fluid connection with the reduced-pressure chamber 26 via a valve group 28. The gas source 29 has multiple gas source units. In the design shown, these are four gas source units 301, 302, 303 and 304. The valve group 28 has an actuatable source valve 31i assigned to each one of the respective gas source units 30i, and a main valve 32. The main valve 32 is in fluid connection with all source valves 31i via fluid conduits. The main valve 32 is disposed between the source valves 31i and the reduced-pressure chamber 26. The respective gas source unit 30i is in fluid connection with the reduced-pressure chamber 26 by the respective source valve 31i and via the main valve 32 arranged in series therewith.

Each of the gas source units 30i may have a corresponding gas vessel comprising the gas to be provided.

The gas source 29 is designed such that it provides, via the gas source units 30i, at least one of the following gases: nitrogen, hydrogen, oxygen, water vapor, CH₄, NH₃, a metal vapor based, for example, on tin (Sn), zinc (Zn), ruthenium (Ru) or iron (Fe), a volatile metal hydride, for example SnH₄, ZnH₂ or PbH₄, or a volatile metal oxide, for example RuO₄, IrO₄, or a volatile metal fluoride, for example MoF₆, IrF₆, WF₆, ReF₆. It is also possible to use a noble gas. It is also possible to provide further gaseous species via the gas source 29 of the reduced-pressure chamber 26. It is also possible to provide lead (Pb) and/or molybdenum as metal vapors. If a metal vapor is provided, this can be accomplished with an evaporator, for example using a spiral-wound filament.

It is also possible to provide isotopes that form the aforementioned gases, i.e., in the case of hydrogen (H2), D2, HD, T2, TD, HT (D: deuterium; T: tritium).

The valves 31i and 32 are each control valves having signal connection with a closed-loop control device 33 of the EUV source module 27.

The closed-loop control device 33 may be designed so as to define, depending on a state of operation of the EUV source module 27 or of the projection exposure apparatus 1, a particular partial pressure of the gas provided respectively via the gas source 29 or of two or more gases provided by the gas source 29. In this case, the closed-loop control device 33 may refer to a stored look-up table in which partial pressure values for the gas(es) that can be provided in each case by the gas source 29 are assigned as a function of the respective state of operation of the projection exposure apparatus 1.

States of operation may be defined via measurements of the gas composition, especially of H2, N2, NH3, O2, H2O, and/or measurements of the concentration of activated species, especially H, N and O radicals or ions, and/or of the measured or calculated temperature of an optical element. In particular, a state of operation can also be defined via the measurement of a change in the reflective layer of an optical element.

In one design of the EUV source module 27, it has at least one pressure sensor 34 for measuring a partial pressure of the at least one gas provided by the gas source 29 in the reduced-pressure chamber 26. In the design shown in FIG. 1, there are two such pressure sensors34₁, 34₂. These pressure sensors 34i are disposed in the reduced-pressure chamber 26 close to the intermediate focus in the intermediate focal plane 18, i.e. measure the partial pressure of the at least one gas provided close to this intermediate focus.

The pressure sensors 34i can measure the partial pressure of each one of the gases which is provided via the gas source units 30i.

In the design with the at least one pressure sensor 34, the closed-loop control device 33 may be designed such that a target value is defined for the respective partial pressure of the at least one gas provided depending on the respective state of operation of the EUV source module 27 or of the projection exposure apparatus 1, and the gas is then provided in the reduced-pressure chamber 26 in a controlled manner using the respective pressure sensor 34i as the actual partial pressure value within the reduced-pressure chamber 26 via the gas source 29 by appropriate actuation firstly of the assigned source valve 31i and secondly of the main valve 32.

Alternatively, a corresponding pressure sensor 34 may also be disposed in the environment of the source region 25, as likewise shown in FIG. 1, where it may measure a corresponding partial pressure of the at least one gas provided.

The pressure sensor 34, 34i may in principle be designed as an optical sensor.

The partial pressure of the at least one gas provided can be kept within a defined pressure range with the open-loop/closed-loop pressure control system that has been explained above, for example in the source region 25. This can be assured by monitoring by the pressure sensor 34 in the environment of the source region 25.

Alternatively or additionally, it is also possible to keep a partial pressure of the at least one gas provided within a defined pressure range in the region of the intermediate focus in the intermediate focal plane 18 with the aid of the above-described open-loop/closed-loop control system. Compliance with the partial pressure can be monitored here by measuring the pressure via the pressure sensors 34₁, 34₂ in the region of the intermediate focus in the intermediate focal plane 18.

In one design (not shown) of the gas source 29, this has injection nozzles for controlled injection of at least one of the gases provided into the reduced-pressure chamber 26 in the environment of the intermediate focus in the intermediate focal plane 18. The amount of the gas injected respectively can then be monitored with the pressure sensors 34₁, 34₂ in the environment of the intermediate focus in the intermediate focal plane 18.

The respective gas can also be supplied to the reduced-pressure chamber 26 via at least one purge conduit.

If nitrogen is being provided, a partial nitrogen pressure in the reduced-pressure chamber 26 in the range between 10 Pa and 100 Pa can be maintained via the above-described open-loop/closed-loop control system. If hydrogen is being provided as gas in the reduced-pressure chamber 26, a partial hydrogen pressure may typically be kept in the range between 30 Pa and 300 Pa.

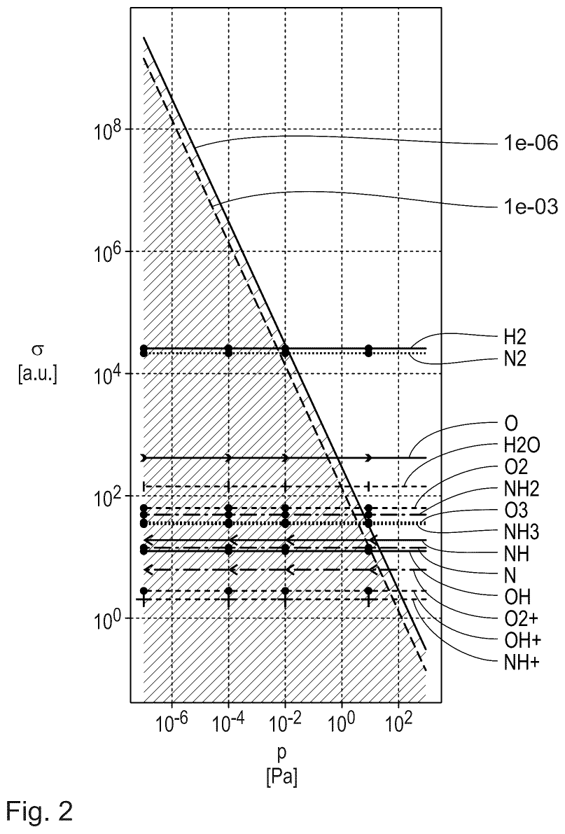

FIG. 2 shows the dependence of an effective cross section σ of different particle species on the partial pressure p thereof. This effective cross section is proportional to the absorption of the respective particle species at particular wavelengths of light or radiation. Additionally shown in FIG. 2 as obliquely declining curves are a transmission of 1e-06 (solid line) and a transmission of 1e-03 (dotted line). Respectively shown in solid/dashed/dashed-and-dotted/dotted form are the effective cross section for H2, H2O, N, N2, NH, NH+, NH2, NH3, O, O2, O2+, O3, OH and OH+. Because of the comparatively large effective cross section of hydrogen and nitrogen, transmissions of 1e-06 and 1e-03 are found for comparatively low partial pressures in the region of 10-2 Pa. For the other particle species, these two 1e-03 transmission values are found only at higher partial pressures, for example in the region of 100 Pa (H2O) or even of even greater partial pressures (for example O2).

In order that there is a significant interaction, for example, of hydrogen or nitrogen with the EUV radiation 16, for example in the source region 25 or in the intermediate focus in the intermediate focal plane 18, a partial pressure of at least 1e-03 must be defined. For the other particle species, a correspondingly higher partial pressure p must be defined, as apparent from the diagram in FIG. 2.

NH3 gas can especially bind nitrogen ions.

FIGS. 3 to 6 show wavelength dependences of a relative transmission T for particular particle species, shown for “in-band”, “VUV” and “DUV” wavebands.

“In-band” refers here to a used EUV wavelength of 13.5 nm.

“VUV” refers to the wavelength range between 70 nm and 130 nm.

“DUV” refers to the wavelength range between 130 nm and 400 nm.

FIG. 3 shows a wavelength dependence of a relative transmission for particular particle species, shown for various wavelength ranges and for a respective partial pressure of 0.001 Pa. The relative transmissions are shown for the particle species tin metal vapor, nitrogen, iron metal vapor and zinc metal vapor, which can be provided in the reduced-pressure chamber 26 by appropriate fitting of the gas source units 30; of the gas source 29, as explained above.

The relative transmission values according to FIG. 3 are normalized to transmission over an in-band wavelength range.

VUV transmission in this pressure range is slightly higher than in-band transmission and is about 1.1. DUV transmission for all these particle species is about 1.4 at the partial pressure of 0.001 Pa.

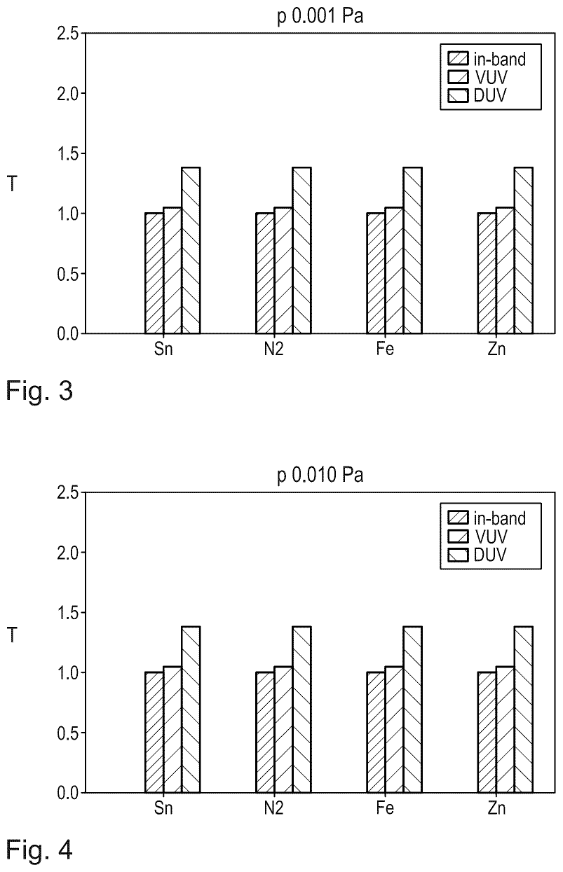

FIG. 4 shows the ratios at a partial particle species pressure of 0.01 Pa, ten times the value in FIG. 3. There is virtually no change by comparison with the relative transmission values according to FIG. 3. It can be concluded from this that the respective particle species still do not have any real influence on the relative transmission of the EUV radiation 16.

FIG. 5 shows the relative transmission values at a partial particle species pressure of 0.1 Pa, which is ten times greater again. The relative transmissions for the DUV wavelength range have slightly increased by comparison with FIGS. 3 and 4 for the particle species tin metal vapor and zinc metal vapor, and are about 1.5 for tin metal vapor and about 1.45 for zinc metal vapor at the partial pressure value of 0.1 Pa in FIG. 5.

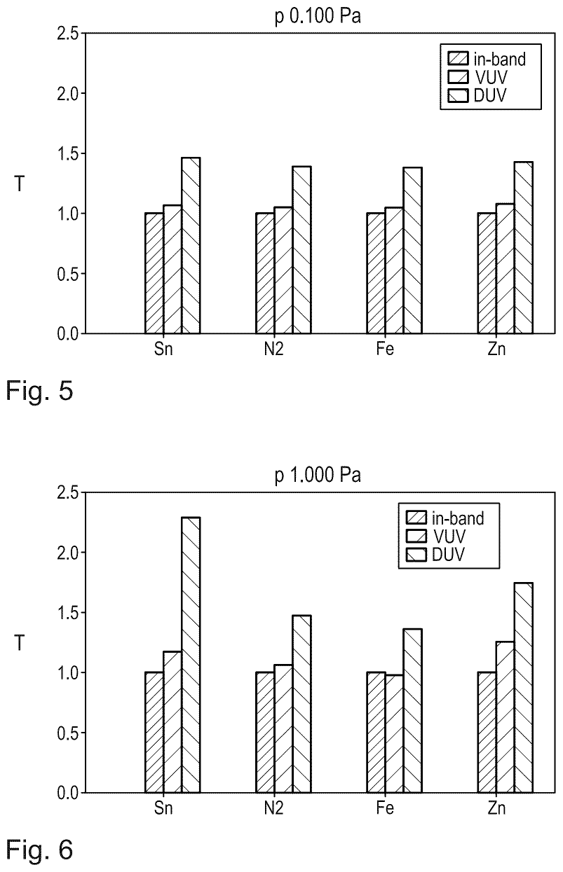

FIG. 6 shows the relative transmission values for the same particle species at a partial pressure of 1.0 Pa, which is ten times higher again. By comparison with the lower partial pressure values, in particular, the relative transmissions for the DUV wavelength range have now increased for the particle species tin metal vapor, nitrogen and zinc metal vapor. For the partial pressure 1.0 Pa, the relative transmissions are now at a value of about 2.3 for tin metal vapor, at a value of about 1.75 for zinc metal vapor, and about 1.5 for nitrogen. The relative transmissions for the VUV wavelength range have also increased for tin metal vapor on the one hand and for zinc metal vapor, and are now about 1.2 for tin metal vapor and about 1.3 for zinc metal vapor.

Tin metal vapor and/or zinc metal vapor in particular can thus be utilized in a partial pressure-dependent manner as effective wavelength filters for the DUV range and also for the VUV range.

This is used, for example, in the projection exposure apparatus in order to selectively filter out unwanted wavelengths or wavelength ranges from radiation components of different wavelengths included in the used EUV radiation 16 that cause unwanted photoreactions with particles present further down the beam path of the used EUV radiation 16. Such unwanted reactions are especially those that lead to reaction products that impair or degrade optical surfaces of components of the projection exposure apparatuses 1 that guide the used EUV radiation 16. Reactions that lead to products having unwanted absorption at the wavelength of the used EUV radiation 16 are also corresponding unwanted reactions.

Filtering via the gas provided can alternatively or additionally be utilized to avoid unwanted photocurrents that would otherwise be generated in the exposed optical component of the projection exposure apparatus 1 by exposure to the wavelengths or wavelength ranges that are now being filtered out. This in particular allows the performance of optical components to be enhanced, in that these overall or their individual components, for example in the form of single mirrors, are held in position with holding currents. It is then possible to avoid any unwanted influence on such components by photocurrents generated. One example of such components is a MEMS mirror system having a multitude of individual single mirrors that are held in a corresponding tilted position with holding currents.

The interaction of the at least one gas provided in the reduced-pressure chamber 26 via the gas source 29 gives rise, further down the beam path of the used EUV radiation 16, to a wavelength distribution of the radiation included in the beam path with the used EUV radiation 16 that reduces or entirely avoids corresponding unwanted reactions and/or photocurrents. The result is attenuation of corresponding absorption lines of an overall radiation spectrum emitted by the source region 25. Wavelength ranges of this overall radiation spectrum that are correspondingly attenuated by the gases provided in the reduced-pressure chamber 26 are then no longer available to cause unwanted degradation and/or also no longer available to cause an unwanted reduction in power as a result of photoinduced misadjustment of the optical components downstream in the beam path of the used EUV radiation 16. In particular, it is possible to reduce or entirely avoid N₂-induced and/or H₂-induced degradation of optical coatings of optical surfaces of these optical components and/or unwanted photoinduced misadjustment of the optical components. N₂/N ion/H₂-induced coating degradation would otherwise be caused by radiation in these wavelength ranges by photoionization and/or photoinduced misadjustment would otherwise be caused by radiation in these wavelength ranges by photocurrents. The attenuation of these wavelength ranges then results in a reduction or complete avoidance of such photoionization. By definition, for example, of a corresponding partial H₂ pressure, it is possible, for example, to avoid unwanted creation of hydrogen plasma further down the beam path of the used EUV radiation 16.

In principle, there are two different ways of avoiding such unwanted reaction products in the at least one gas provided:
Firstly, corresponding photoionization reactions can be induced within the reduced-pressure chamber 26 of the EUV source module 27 by addition of appropriate partial gas pressures, such that radiation wavelengths that are used in these disruptive photoionizating processes are no longer available further down the beam path of the used EUV radiation 16. By inducing the disruptive reaction in the beam path before the intermediate focus in the intermediate focal plane 18, the reaction in the beam path downstream of the intermediate focus in the intermediate focal plane 18 is then reduced or entirely avoided in a desirable manner. An example of this controlled inducement of reaction are photoionization processes on nitrogen particle species and/or hydrogen particle species.
Secondly, a radiation wavelength at which an unwanted reaction, especially a photoionization, for creation of unwanted reaction products is known to take place, or unwanted photocurrents are known to be generated, can be attenuated with a filter used in a controlled manner, especially a bandpass filter which is formed by the at least one gas provided, such that such disruptive photoionization/photocurrent wavelengths are no longer available for the creation of unwanted reaction products in the beam path of the used EUV radiation 16 downstream of the intermediate focus in the intermediate focal plane 18. One example of such a bandpass filter is the metal vapors described above, for example in association with FIGS. 3 to 6, based on tin, zinc or iron, or else nitrogen. Nitrogen and hydrogen gas species may act, for example, as line filters. With the aid of such a bandpass filter, it is especially possible to wholly or partly suppress a wavelength range between 40 nm and 170 nm, which has been found to be troublesome with regard to the creation of unwanted photocurrents.

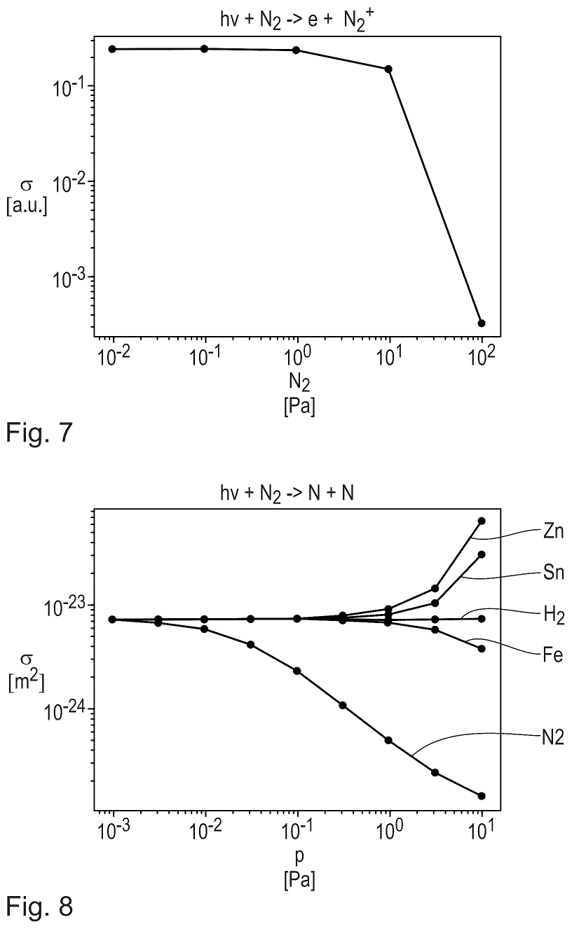

FIG. 7 shows the dependence of an effective N2 effective cross section σ close to an optical surface of an optical component downstream of the intermediate focus in the intermediate focal plane 18 on a partial nitrogen pressure p in the reduced-pressure chamber 26 in the environment of the source region 25 and/or in the environment of the intermediate focus in the intermediate focal plane 18. Over and above a partial nitrogen pressure of 101 Pa, a distinct reduction in this effective N2 dissociation effective cross section is found, which drops by more than one order of magnitude between 10 Pa and 100 Pa.

This effective effective cross section σ is reported in arbitrary units (a.u.).

The drop in the effective effective cross section σ in FIG. 7 for higher partial N2 pressures leads, for example, to a corresponding reduction in disruptive photoionization of nitrogen to give a nitrogen ion N2+ and an electron. If this photoionization reaction is reduced or entirely avoided in the environment of the optical surface of the optical component, N2+ ions cannot contribute to degradation of the optical surface.

FIG. 8 shows a corresponding dependence of effective cross section on partial pressure for the photoinduced splitting, close to an optical surface, of a nitrogen molecule into two nitrogen atoms or into two nitrogen ions.

An effective effective cross section of the respectively considered element species is reported in FIG. 8 in the unit m2.

Above a partial nitrogen pressure p in the reduced-pressure chamber 26 of 10-2 Pa, there is a drop in the effective N2 effective cross section σ by more than one order of magnitude for this photoinduced splitting.

Reduction in the effective N2 effective cross section for this photoinduced splitting results in a corresponding reduction of disruptive nitrogen atoms or nitrogen ions in the region of the optical surfaces of the optical components in the beam path of the EUV radiation 16 downstream of the intermediate focus in the intermediate focal plane 18.

The optical components, the degradation of which can be reduced or entirely avoided in this way or the performance of which can be increased, are firstly optical components of the illumination optical unit 4 and/or secondly the optical components of the projection optical unit 10, i.e. the mirrors Mi.

FIG. 8 additionally shows the influence firstly of iron metal vapor (Fe) and secondly of zinc metal vapor (Zn) on the photoinduced splitting of a nitrogen molecule into two nitrogen atoms or nitrogen ions, again close to an optical surface of the optical component to be protected. Depending on the partial iron pressure, there is a drop in the effective N₂ effective cross section σ above a partial iron metal vapor pressure of 10° proceeding from a starting value of about 8×10⁻²⁴ m² to values of less than 4×10⁻²⁴ m², i.e. by more than a factor of 2. Correspondingly, when such metal vapors with these partial pressures are used within the reduced-pressure chamber 26, for example in the environment of the source region 25 or close to the intermediate focus in the intermediate focal plane 18, the result is a desired reduction in this splitting reaction in the beam path of the used EUV radiation 16 downstream of the intermediate focus in the intermediate focal plane 18 and corresponding protection of the downstream optical components of the illumination optical unit 4 and the projection optical unit 10.

When a zinc metal vapor is used, above a corresponding partial Zn metal vapor pressure of 100 Pa, there is an increase in the effective N2 effective cross section for this splitting reaction. In the case of a partial Zn metal vapor pressure of 101 Pa, an N2 effective cross section greater than 5×10−23 m2 is achieved.

When a hydrogen vapor is used, no significant dependence of the N2 effective cross section on the partial H2 pressure is found.

Similar behavior is found when a tin metal vapor (Sn) is used. In that case, above a partial Sn metal vapor pressure of 100 Pa, an increase in the effective N2 effective cross section is found, again proceeding from about 8×10−24 m2 to more than 2×10−23 m2.

The tin metal vapor efficiently suppresses the wavelength range between 80 nm and 160 nm in particular.

In a further design of the projection exposure apparatus 1, which is used alternatively or additionally to that with the gas source 29 and/or the sensors 34 for the reduced-pressure chamber of the EUV source module 27, an EUV optics module 35 is used, which is described hereinafter.

The EUV optics module 35 has a reduced-pressure chamber 36 that accommodates the illumination optical unit 4 and the projection optical unit 10.

Reduced pressure is generated in the reduced-pressure chamber 26 and 36 by at least one reduced-pressure source, for example a vacuum pump, which is not shown in FIG. 1.

The reduced-pressure chamber 36 includes all the optical components of the projection exposure apparatus 1 that guide the used EUV radiation 16 downstream of the intermediate focus in the intermediate focal plane 18. In the beam path of the used EUV radiation 16 downstream of the intermediate focus in the intermediate focal plane 18, these are the optical components 19, 21, 23, the reticle 7, M1 to M6, and the wafer 13.

These optical components each have an optical surface for guiding of the used EUV radiation 16 from the EUV source module 27 including the EUV source along the illumination and/or imaging beam path of the used EUV radiation 16 within the projection exposure apparatus 1.

The optical components may be of temperature-controllable design.

The EUV optics module 35 in turn has a gas source 37 fluidically connected via at least one valve 32a to the reduced-pressure chamber 36. The construction of the gas source 37 with at least one gas source unit 30i and with a valve group 28a including the source valves 31i each assigned to the gas source units 30i and the main valve 32a corresponds to the construction of the gas source 29 that has already been detailed above in connection with the EUV source module 27.

The gas source 37 is designed such that it provides the reduced-pressure chamber 36 at least with hydrogen as gas. It is also possible to provide other gases, for example oxygen and/or nitrogen, especially also in the form of vapors, as already explained above in connection with the EUV source module 27, via the gas source 37.

The gas source 37 may have gas nozzles or injection nozzles that are directed onto the respective optical surfaces of the optical components 19, 21, 23, 7, M1 to M6, 13. This ensures that the activated hydrogen species are generated where they are used for cleaning of the optical surfaces of the respective optical component. It is also possible to provide a multitude of corresponding gas nozzles (not shown in FIG. 1) for each optical surface of the optical component. The gas source 37 and especially the controllable valves thereof are in signal connection with the open-loop/closed-loop control device 33 of the projection exposure apparatus 1.

The hydrogen gas provided by the gas source 37 leads, within the reduced-pressure chamber 36, to generation of at least one activated hydrogen species which is used for reaction with an unwanted contamination component within the reduced-pressure chamber 36, especially for cleaning of the optical surfaces of the optical components 19, 21, 23, 7, M1 to M6, and 13. In this way, the respective optical surface is effectively cleaned. The definition of the partial hydrogen pressure in the reduced-pressure chamber 36 achieves the desired generation of the activated hydrogen species therein.

The other gases that can be introduced into the reduced-pressure chamber 36 via the gas source 37 in addition to hydrogen, for example oxygen and/or nitrogen, may likewise serve for production, for example, of cleaning radicals for cleaning of the optical surfaces of the optical components of the illumination optical unit 4 and/or of the projection optical unit 10, and/or may serve, analogously to what has been described above in association with the EUV source module 27, to filter radiation included in the EUV light radiation 16, which reduces or completely avoids generation of unwanted reaction components that could otherwise lead to degradation of the optical surfaces.

One option is to operate the EUV optics module 35 with control purely via the open-loop/closed-loop control device 33, i.e. with the aid of a lookup table depending on states of operation of the EUV optics module 35 or of the overall projection exposure apparatus 1, for example. Alternatively or additionally, the gas source 37 can also be operated under closed-loop control. For such closed-loop control operation, the EUV optics module 35 in turn has pressure sensors 38i which, in FIG. 1, are indicated as being assigned as pressure sensors 381 to 3811 to the optical surfaces of the optical component 19, 21, 23, 7, M1 to M6, and 13. The function of these pressure sensors 38i, which are in turn in signal connection with the open-loop/closed-loop control device 33, corresponds to that of the pressure sensors 34i of the EUV source module 27.

In particular, with the aid of the pressure sensors 38i, it is possible to measure a partial hydrogen pressure.

The partial pressure measured via the respective pressure sensor 38, as already described above in connection with the EUV source module 27, can especially be kept in a defined pressure range with the open-loop/closed-loop control device 33.

The partial hydrogen pressure within the reduced-pressure chamber 36 can be kept, for example, in the range between 0.2 Pa and 20 Pa.

It is possible to admit isotopes of the respective gases, especially hydrogen isotopes, into the reduced-pressure chamber 36 and optionally also into the reduced-pressure chamber 26 of the EUV source module 27 via the respective gas sources 37 or 29.

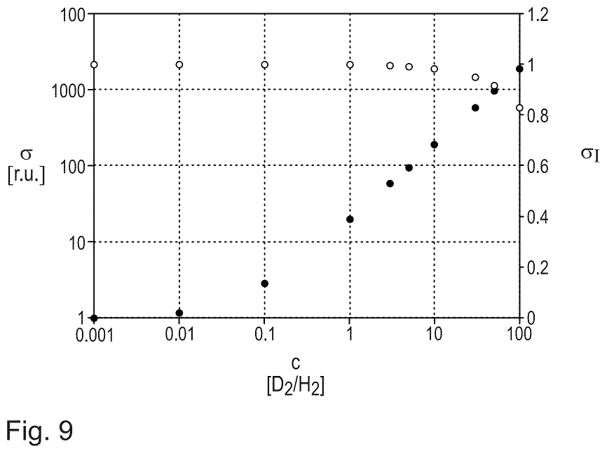

FIG. 9 shows a dependence of an effective effective cross section σ for photoinduced splitting of molecular hydrogen species (H2 and/or D2) on an isotope concentration c of deuterium D2 in hydrogen H2 for a given proportion of D2/H2 in the reduced-pressure chamber 36 or 26. The dependence shown in FIG. 9 is valid here especially for a partial D2/H2 pressure of 0.2-20 Pa within the reduced-pressure chamber 36 or 26.

What is shown, in solid circles, is a dependence of this effective dissociation cross section σ on the concentration c (D2/H2), reported in relative units [r.u.], based on a dissociation cross section of exactly 1 for pure hydrogen (c (D2/H2)=0).

Additionally shown, in open circles, is the dependence of a relative effective cross section al for a photoinduced ionization of molecular hydrogen species (H2 and/or D2). What is shown here is the ionization cross section σI in relation to a value of exactly 1 for a pure hydrogen content (c (D2/H2)=0).

The dissociation cross section σ, above a relative concentration c of 0.01, rises rapidly by several orders of magnitude, and at a concentration c (D2/H2) of 10% is more than 100. At this concentration, there has barely been any reduction in the ionization cross section GI, which is essentially constant for concentrations c in the range between 0.001% and 1%.

The dependences in FIG. 9 show that addition of, for example, 10% or 25% deuterium causes a rapid advantageous rise in the dissociation cross section, while there is no unwanted drop in the ionization cross section. This corresponding addition of deuterium thus allows, for example, an increase in the proportion of reactive hydrogen species in the reduced-pressure chamber 36 or 26, which can achieve more effective cleaning and/or reaction of the optical surfaces of the optical components. Advantageous isotope concentration fractions c (D2/H2) are in the range between 0.02% and 25% and, for example, in the range between 0.1% and 10%.

In the design according to FIG. 1, the reduced-pressure chamber 36 encloses both the illumination optical unit 4 and the projection optical unit 10. Alternatively, the reduced-pressure chamber 36 may also be subdivided into a first subchamber which encloses exclusively the illumination optical unit 4, and a second subchamber which encloses exclusively the projection optical unit 10. Accordingly, the EUV optics module 35, if it is connected to one of these subchambers, may function as part of the illumination optical unit 4 and/or as part of the projection optical unit 10.

In order to produce a microstructured or nanostructured component, the projection exposure apparatus 1 is used as follows: First, the reflection mask 7 or the reticle and the substrate or the wafer 13 are provided. Subsequently, a structure on the reticle 7 is projected onto a light-sensitive layer of the wafer 13 with the aid of the projection exposure apparatus 1. Then a microstructure or nanostructure on the wafer 13, and hence the microstructured component, is produced by developing the light-sensitive layer.

What is claimed is:

1. An extreme ultraviolet (EUV) optics module for an EUV projection exposure apparatus, comprising:
at least one optical component having an optical surface arranged to guide used EUV radiation along an illuminating and/or imaging beam path of the projection exposure apparatus,
a reduced-pressure chamber configured to accommodate the optical component,
a gas source fluidically connected via at least one valve to the reduced-pressure chamber,
wherein the gas source is configured to provide hydrogen as an at least one gas,
wherein the gas source is configured to add to the at least one gas provided at least one isotope of the gas in a controlled concentration.

2. The EUV optics module according to claim 1, wherein the gas source) is configured such that addition of hydrogen isotopes increases an effective cross section of the gas for dissociative generation of reactive hydrogen species proportionally by more than three orders of magnitude relative to an EUV optics module without an addition of isotopes.

3. The EUV optics module according to claim 2, wherein a proportion of an isotope corresponds to 0.02-25% of the at least one gas provided.

4. The EUV optics module according to claim 2, further comprising a closed loop control configured to adjust a concentration of the isotope in the gas provided in accordance with an operation state of the module.

5. The EUV optics module according to claim 1, wherein the valve is a control valve having a signal connection to an open-loop/closed-loop control device of the EUV optics module.

6. The EUV optics module according to claim 5, further comprising at least one pressure sensor arranged to measure a partial pressure of the at least one gas provided via the gas source in the reduced-pressure chamber, wherein the pressure sensor has signal connection to the control valve via the open-loop/closed-loop control device.

7. The EUV optics module according to claim 1, further comprising a control device configured to maintain a partial pressure of the at least one gas provided in a defined pressure range within an environment of the optical surface of the optical component.

8. The EUV optics module according to claim 1, further comprising a control device configured to maintain a partial hydrogen pressure in a range between 0.2 Pa and 20 Pa in the reduced-pressure chamber.

9. The EUV optics module according to claim 1, wherein the gas source is configured to provide at least one further gas selected from the group consisting of:
oxygen and/or
water vapor and/or
nitrogen and/or
CH₄ and/or
NH₃ and/or
CO and/or
CO₂.

10. An optical system for an EUV projection exposure apparatus, comprising:
an illumination optical unit configured to illuminate an object field,
a support for an object disposed in the object field, and
an imaging optical unit configured to image the object field in an image field,
a support for a wafer disposed in the image field, and
an EUV optics module according to claim 1 and incorporated into the illumination optical unit.

11. An optical system for an EUV projection exposure apparatus, comprising:
an illumination optical unit configured to illuminate an object field
a support for an object disposed in the object field, and
an imaging optical unit configured to image the object field in an image field,
a support for a wafer disposed in the image field, and
an EUV optics module according to claim 1 and incorporated into the imaging optical unit.

12. A projection exposure apparatus, comprising:
an optical system according to claim 10, and
an EUV light source generating the EUV radiation.

13. A projection exposure apparatus, comprising:
an optical system according to claim 11, and
an EUV light source generating the EUV radiation.

14. A method for producing a structured component, comprising:
providing a reticle and a wafer,
projecting a structure on the reticle onto a light-sensitive layer of the wafer with a projection exposure apparatus according to claim 12, and
producing a microstructure or nanostructure on the wafer.

15. A method for producing a structured component, comprising:
providing a reticle and a wafer,
projecting a structure on the reticle onto a light-sensitive layer of the wafer with a projection exposure apparatus according to claim 13, and
producing a microstructure or nanostructure on the wafer.
